(19) United States
(12) Patent Application Publication
(10) Pub. No.: US 2025/0268077 A1
(43) Pub. Date: Aug. 21, 2025

(54) DISPLAY APPARATUS HAVING OPTICAL LENSES

(71) Applicant: LG Display Co., Ltd., Seoul (KR)

(72) Inventors: Ju Seong PARK, Paju-si (KR); Joung Won WOO, Paju-si (KR); Wook JEON, Paju-si (KR)

(73) Assignee: LG Display Co., Ltd., Seoul (KR)

(21) Appl. No.: 18/946,194

(22) Filed: Nov. 13, 2024

(30) Foreign Application Priority Data
Feb. 20, 2024 (KR) 10-2024-0024484

(51) Int. Cl. H10K 59/80; H10K 59/122; H10K 59/126; H10K 59/38

(52) U.S. Cl. CPC H10K 59/879; H10K 59/122; H10K 59/126; H10K 59/38; H10K 59/877

(57) ABSTRACT

A display apparatus may include optical lenses disposed on light-emitting devices. The light-emitting devices can be disposed in emission areas defined by a bank insulating layer. Each optical lens can overlap a light-emitting device and the bank insulating layer. A first barrier pattern, a second barrier pattern, color filters and pixel lenses can be disposed between the light-emitting devices and the optical lenses. The first and second barrier patterns can be stacked on the bank insulating layer. The color filters and pixel lenses can be stacked in the emission areas. The pixel lenses can be disposed between the first and second barrier patterns. A diffusing layer can be disposed between the pixel lenses and the optical lenses and between the second barrier pattern and the optical lenses. Thus, in the display apparatus, the visibility of the second barrier pattern can be reduced, and the image quality can be improved.

### CROSS-REFERENCE TO RELATED APPLICATIONS

This application claims the benefit of and priority to Korean Patent Application No. 10-2024-0024484, filed on Feb. 20, 2024, the entire contents of which are incorporated herein by reference for all purposes.

### BACKGROUND

### 1. Technical Field

The present disclosure relates to a display apparatus, and particularly to, for example, without limitation, a display apparatus in which optical lenses are disposed on light-emitting devices.

### 2. Discussion of the Related Art

Generally, a display apparatus provides an image to a user. For example, the display apparatus can include light-emitting devices disposed on pixel areas of a device substrate. Each of the light-emitting devices can emit light displaying a specific color. For example, each of the light-emitting devices can include a first electrode, a light-emitting layer and a second electrode, which are sequentially stacked on the device substrate.

The image provided by the display apparatus can be three-dimensionally recognized by the user. For example, the display apparatus can include optical lenses disposed on the light-emitting devices. The optical lenses can extend parallel to each other in a direction. For example, the optical lenses can be a lenticular lens for realizing three-dimensional images using a light field method.

A barrier pattern can be disposed between the pixel areas. The barrier pattern can be disposed between the light-emitting devices and the optical lenses. For example, light emitted from the light-emitting device of each pixel area toward the optical lens disposed on an adjacent pixel area can be blocked by the barrier pattern. However, in the display apparatus, the barrier pattern can be enlarged by the optical lenses. Thus, in the display apparatus, the barrier pattern enlarged by the optical lenses can be recognized by the user. Therefore, in the display apparatus, the quality of the image recognized by the user can be decreased.

The description of the related art should not be assumed to be prior art merely because it is mentioned in or associated with this section. The description of the related art includes information that describes one or more aspects of the subject technology, and the description in this section does not limit the invention.

### SUMMARY

Accordingly, one or more aspects of the present disclosure are directed to a display apparatus that substantially obviates one or more problems due to limitations and disadvantages of the related art.

One or more aspects of the present disclosure are to provide a display apparatus capable of increasing the quality of the image recognized by the user.

One or more other aspects of the present disclosure are to provide a display apparatus capable of reducing the visibility of the barrier pattern due to the optical lenses.

Additional advantages, aspects, and features of the disclosure will be set forth in part in the description which follows and in part will become apparent to those having ordinary skill in the art upon examination of the following or can be learned from practice of the disclosure. The advantages, aspects, and features of the disclosure can be realized and attained by the structure particularly pointed out in the written description and claims hereof as well as the appended drawings.

To achieve these and other advantages and aspects of the present disclosure, as embodied and broadly described herein, in one or more aspects, there is provided a display apparatus comprising a device substrate, an emission area, and a non-emission area. A light-emitting device is disposed at or in the emission area. A color filter and a first barrier pattern are disposed on the light-emitting device. The color filter overlaps the emission area. A first barrier pattern overlaps the non-emission area. A pixel lens is disposed on the color filter and the first barrier pattern. The pixel lens overlaps the emission area. A second barrier pattern is disposed on the pixel lens. The second barrier pattern overlaps the first barrier pattern. An optical lens is disposed on the pixel lens and the second barrier pattern. The optical lens overlaps the emission area and the non-emission area. A diffusing layer is disposed between the pixel lens and the optical lens and between the second barrier pattern and the optical lens.

The optical lens can include a different material from the pixel lens.

The pixel lens can include an end portion overlapping with the non-emission area.

The end portion of the pixel lens can overlap the first barrier pattern and the second barrier pattern.

The second barrier pattern can be spaced apart from the pixel lens and the diffusing layer.

The second barrier pattern can include a same material as the first barrier pattern.

The pixel lens can be covered by a first optical insulating layer. A second optical insulating layer can be disposed on the first optical insulating layer. The second barrier pattern can be disposed between the first optical insulating layer and the second optical insulating layer. The diffusing layer and the optical lens can be stacked on the second optical insulating layer. The first optical insulating layer can have a refractive index smaller than the pixel lens.

A curvature of the optical lens can be different from a curvature of the pixel lens.

The light-emitting device can include a light-emitting layer disposed between a first electrode and a second electrode. Light generated by the light-emitting layer cab display a same color as light passing through the color filter.

In one or more aspects, there is provided a display apparatus comprising a device substrate. A bank insulating layer is disposed on the device substrate. The bank insulating layer defines emission areas. Light-emitting devices are disposed in or at the emission areas. Color filters and a first barrier pattern are disposed on the light-emitting devices. The color filters overlap the emission areas. The first barrier pattern is disposed side by side the color filters. A second barrier pattern is disposed on the first barrier pattern. The first barrier pattern and the second barrier pattern overlap the bank insulating layer. Pixel lenses are disposed between the first barrier pattern and the second barrier pattern. The pixel lenses overlap the emission areas. A diffusing layer is disposed on the second barrier pattern. The diffusing layer overlaps the emission areas and the bank insulating layer. Optical lenses are disposed on the diffusing layer. The optical lenses extend parallel to each other in a direction. Each of the optical lenses includes a region overlapping with a respective one of the emission areas and a region overlapping with the bank insulating layer.

Each of the pixel lenses can be spaced apart from an adjacent pixel lens on the bank insulating layer.

The second barrier pattern can include a different material from the first barrier pattern.

Each of the color filters can include a different material from an adjacent color filter. The first barrier can have a structure in which the color filters displaying different colors are stacked.

Each of the pixel lenses can overlap one of the emission areas. A plane of each pixel lens can have a different shape from a plane of the corresponding emission area.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K region in FIG. 1;

FIG. 4 is a view taken along I-I′ of FIG. 3;

FIG. 5A is a view showing an image by a display apparatus without pixel lenses and a diffusing layer, and FIG. 5B is a view showing an image by the display apparatus according to the embodiment of the present disclosure; and

FIGS. 6 and 7 are views showing the display apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, aspects, technical configurations, and operational effects of the embodiments of the present disclosure will be provided in more detail using the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. For example, an element may be one or more elements. An element may include a plurality of elements. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless “directly” is used, the terms “connected” and “coupled” can include that two components are “connected” or “coupled” through one or more other components located between the two components.

Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

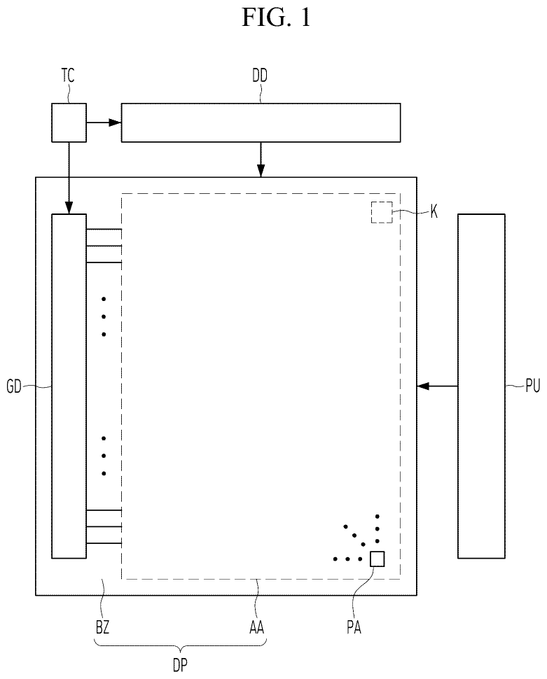

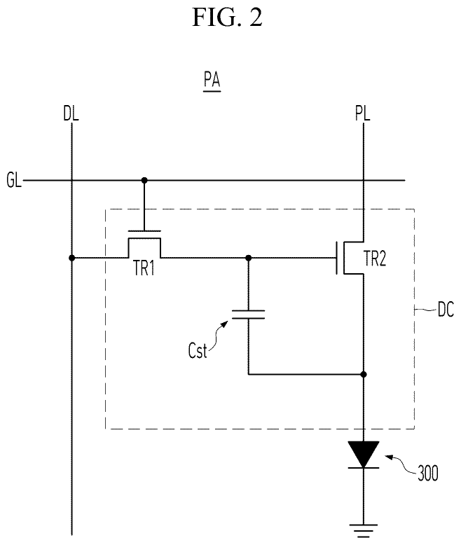

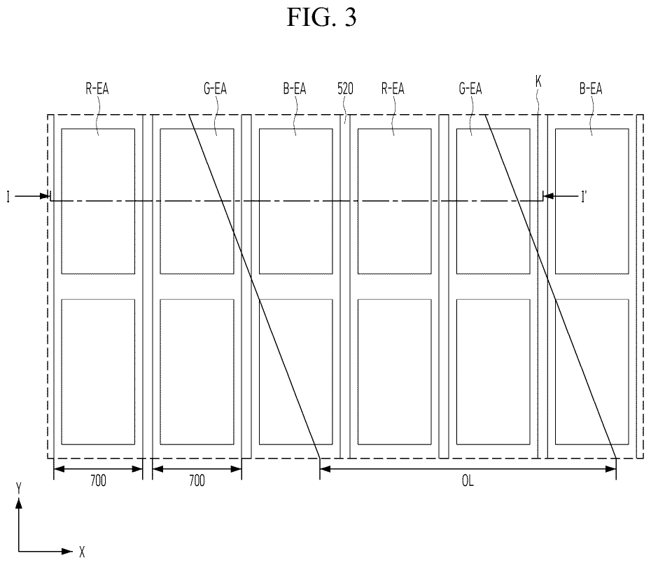

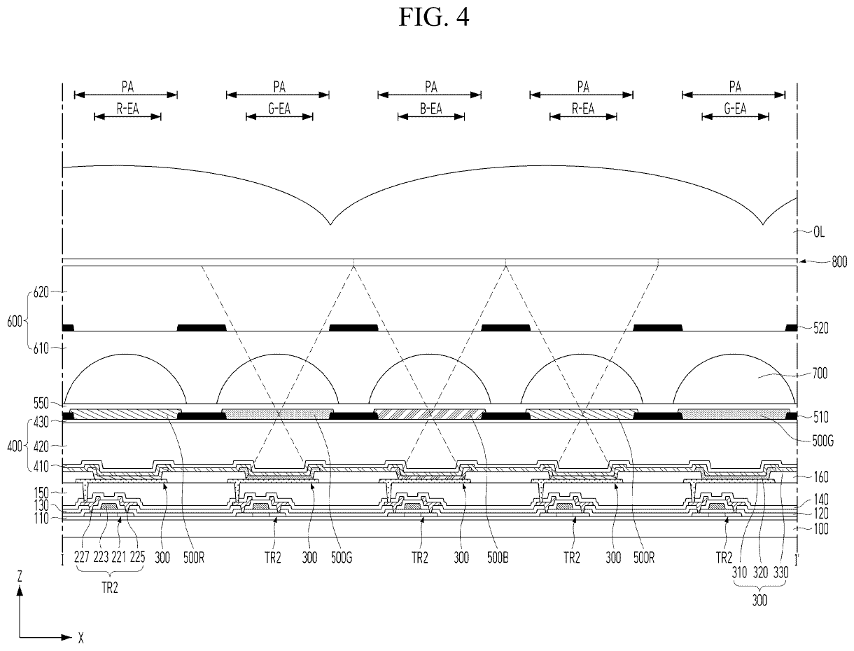

FIG. 1 is a view schematically showing a display apparatus according to an embodiment of the present disclosure. FIG. 2 is a view showing a circuit of a pixel area in the display apparatus according to the embodiment of the present disclosure. FIG. 3 is an enlarged view of K region in FIG. 1. FIG. 4 is a view taken along I-I′ of FIG. 3.

Referring to FIGS. 1 to 4, the display apparatus according to the embodiment of the present disclosure can include a display panel DP. The display panel DP can generate an image provided to a user. For example, pixel areas PA can be disposed in the display panel DP. Various signals can be provided in each pixel area PA through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC. The power voltage supply lines PL can be electrically connected to a power unit PU.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. The gate driver GD, the data driver DD, the timing controller TC and the power unit PU can be disposed outside the active area AA. For example, each of the signal wirings GL, DL and PL can include a region disposed on the bezel area BZ.

At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color according to the signal applied through the signal wirings GL, DL and PL. For example, a driving circuit DC electrically connected to a light-emitting device 300 can be disposed in each pixel area PA. The driving circuit DC of each pixel area PA can control the light-emitting device 300 of the corresponding pixel area PA according to signals applied to the signal wirings GL, DL and PL. For example, the driving circuit DC of each pixel area PA can supply a driving current corresponding to the data signal to the light-emitting device 300 of the corresponding pixel area PA according to the gate signal. The driving current supplied by the driving circuit DC of each pixel area PA can be maintained for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The first semiconductor pattern can include a semiconductor material. For example, the first semiconductor pattern can include Low-Temperature Poly-Si (LTPS) or an oxide semiconductor, such as IGZO. The first semiconductor pattern can include a first drain region, a first channel region and a first source region. The first channel region can be disposed between the first drain region and the first source region. The first drain region and the first source region can have a resistance smaller than the first channel region. For example, the first drain region and the first source region can include a conductive region of an oxide semiconductor. The first channel region can be a region of an oxide semiconductor, which is not made as a conductive region.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 of each pixel area PA can be electrically connected to the first source electrode, and the second drain electrode 225 of each pixel area PA can be electrically connected to the corresponding power voltage supply line PL.

The second semiconductor pattern 221 can include a semiconductor material. For example, the second semiconductor pattern 221 can include Low-Temperature Poly-Si (LTPS) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a resistance smaller than the second channel region. For example, the second drain region and the second source region can include a conductive region of an oxide semiconductor. The second channel region can be a region of an oxide semiconductor, which is not made as a conductive region.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed a same layer as the first drain electrode. The second drain electrode 225 can include a same material as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA can maintain a voltage applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 233 of the corresponding pixel area PA, and a second capacitor electrode electrically connected to the second source electrode 227 of the corresponding pixel area PA.

The first capacitor electrode and the second capacitor electrode of each pixel area PA can be formed by using a process of forming the first thin film transistor TR1 and the second thin film transistor TR2 in the corresponding pixel area PA. For example, the first capacitor electrode of each pixel area PA can be disposed on a same layer as the second gate electrode 223 of the corresponding pixel area PA, and the second capacitor electrode of each pixel area PA can be disposed on a same layer as the second source electrode 227 of the corresponding pixel area PA. The first capacitor electrode of each pixel area PA can include a same material as the second gate electrode 223 of the corresponding pixel area PA, and the second capacitor electrode of each pixel aera PA can include a same material as the second source electrode 227 of the corresponding pixel area PA. The first capacitor electrode of each pixel area PA can be formed by a same process as the second gate electrode 223 of the corresponding pixel area PA, and the second capacitor electrode of each pixel area PA can be formed by a same process as the second source electrode 227 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA. Thus, in the display apparatus according to the embodiment of the present disclosure, a process of forming the driving circuit DC in each pixel area PA can be simplified.

The light-emitting device 300 and the driving circuit DC of each pixel area PA can be supported by a device substrate 100. For example, the light-emitting device 300 and the driving circuit DC of each pixel area PA can be disposed on the device substrate 100. The device substrate 100 can include an insulating material. For example, the device substrate 100 can include glass or plastic.

A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed on the device substrate 100. The buffer insulating layer 110 can prevent pollution due to the device substrate 100 in a process of forming the driving circuit DC of each pixel area PA. For example, the buffer insulating layer 110 can extend along an upper surface of the device substrate 100 toward the driving circuit DC of each pixel area PA. The driving circuit DC of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each pixel area PA can be insulated from the first gate electrode of the corresponding pixel area PA by the interlayer insulating layer 130. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent the damage of the driving circuit DC in each pixel area PA due to external impact and moisture. For example, the first drain electrode, the first source electrode, the second drain electrode 225 and the second source electrode 227 of each pixel area PA can be covered by the device passivation layer 140. The device passivation layer 140 can extend beyond the driving circuit DC in each pixel area PA. The device passivation layer 140 can include an insulating material. For example, the device passivation layer 140 can be a linear insulating layer made of an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be a flat. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each pixel area PA can be disposed on the planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the planarization layer 150 of the corresponding pixel area PA.

The first electrode 310 can include a conductive material. The first electrode 310 can include a material having a relatively high reflectance. For example, the first electrode 310 can include a metal, such as aluminum (Al) or silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting layer 320 can generate light having luminance corresponding to a voltage difference between the first electrode 310 and the second electrode 330. For example, the light-emitting layer 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting layer 320 can have a multi-layer structure. For example, the light-emitting layer 320 can include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting layer 320 can be emitted outside through the second electrode 330. The second electrode 330 can have a work-function smaller than the first electrode 310. For example, the first electrode 310 can function as anode electrode, and the second electrode 330 can function as cathode electrode.

The bank insulating layer 160 can be disposed on the planarization layer 150. The bank insulating layer 160 can define an emission area R-EA, G-EA and B-EA in each pixel area PA. The first electrode 310 of each pixel area PA can be insulated from the first electrode 310 of adjacent pixel area PA by the bank insulating layer 160. For example, an edge of the first electrode 310 in each pixel area PA can be covered by the bank insulating layer 160. The first electrode 310 of each pixel area PA can be partially exposed by the bank insulating layer 160. The light-emitting layer 320 and the second electrode 330 of each pixel area PA can be stacked on a portion of the corresponding first electrode 310 exposed by the bank insulating layer 160. For example, the light-emitting layer 320 can be in direct contact with the first electrode 310 and the second electrode 330 at or in the emission area R-EA, G-EA and B-EA of each pixel area PA. The bank insulating layer 160 can include an insulating material. For example, the bank insulating layer 160 can be an organic insulating material. The bank insulating layer 160 can include a different material from the planarization layer 150.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the device passivation layer 140 and the planarization layer 150. The device passivation layer 140 and the planarization layer 150 can include pixel contact holes partially exposing the second source electrode 227 of each pixel area PA. The first electrode 310 of each pixel area PA can be connected to the second source electrode 227 of the corresponding pixel area PA through one of the pixel contact holes. The pixel contact holes can overlap the bank insulating layer 160. Thus, in the display apparatus according to the embodiment of the present disclosure, the change in the location of the first electrode in the emission area R-EA, G-EA and B-EA of each pixel area PA can be minimized. For example, a portion of the first electrode 310 overlapping with the emission area R-EA, G-EA and B-EA of each pixel area PA can be in direct contact with the upper surface of the planarization layer 150. Therefore, in the display apparatus according to the embodiment of the present disclosure, luminance deviation according to the generating location of the light emitted from the emission area R-EA, G-EA and B-EA of each pixel area PA can be prevented.

The image realized by light emitted from the light-emitting device 300 of each pixel area PA can include various colors. The light emitted from the light-emitting device 300 of each pixel area PA can display a different color from the light emitted from the light-emitting device 300 of adjacent pixel area PA. For example, the emission area R-EA, G-EA and B-EA of each pixel area PA can be one of a red emission area R-EA in which red light displaying red color is emitted, a green emission area G-EA in which green light displaying green color is emitted, and a blue emission area B-EA in which blue light displaying blue color is emitted. The light-emitting layer 320 of each pixel area PA can be spaced apart from the light-emitting layer 320 of adjacent pixel area PA. For example, the light-emitting layer 320 of each pixel area PA can be one of a red light-emitting layer generating the red light, a green light-emitting layer generating the green light and a blue light-emitting layer generating the blue light. The light-emitting layer 320 of each pixel area PA can include a different material from the light-emitting layer 320 of adjacent pixel area PA. For example, the light-emitting layer 320 of each pixel area PA can have a stacked structure different from the light-emitting layer 320 of adjacent pixel area PA. The light-emitting layer 320 of each pixel area PA can include an end portion disposed on the bank insulating layer 160.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can extend beyond the corresponding pixel area PA. For example, the second electrode 330 of each pixel area PA can be in direct contact with the second electrode 330 of adjacent pixel area PA on the bank insulating layer 160. Thus, in the display apparatus according to the embodiment of the present disclosure, a process of forming the second electrode 330 in each pixel area PA can be simplified. And, in the display apparatus according to the embodiment of the present disclosure, the luminance of the light generated by the light-emitting layer 320 of each pixel area PA can be adjusted by the data signal applied to the driving circuit DC of the corresponding pixel area PA.

An encapsulation structure 400 can be disposed on the light-emitting device 300 of each pixel area PA. The encapsulation structure 400 can prevent damage of the light-emitting device 300 in each pixel area PA due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting device 300 in each pixel area PA due to the external impact and moisture can be effectively prevented. A thickness difference due to the light-emitting device 300 of each pixel area PA can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface. The upper surface of the encapsulation structure 400 can be parallel to the upper surface of the device substrate 100.

Color filters 500R, 500G and 500B can be disposed on the encapsulation structure 400. Each of the color filter 500R, 500G and 500B can overlap the emission area R-EA, G-EA and B-EA of one of the pixel areas PA. For example, the color filter 500R, 500G and 500B can include a red color filter 500R overlapping with the red emission area R-EA, a green color filter 500G overlapping with the green emission area G-EA, and a blue color filter 500B overlapping with the blue emission area B-EA. The light generated by the light-emitting device 300 of each pixel area PA can emit through the color filter 500R, 500G and 500B of the corresponding pixel area PA.

Thus, in the display apparatus according to the embodiment of the present disclosure, the color reproduction can be improved.

The color filter 500R, 500G and 500B of each pixel area PA can have a greater size than the emission area R-EA, G-EA and B-EA of the corresponding pixel area PA. For example, the color filter 500R, 500G and 500B of each pixel area PA can include a region disposed outside the emission area R-EA, G-EA and B-EA defined in the corresponding pixel area PA. A region disposed between adjacent emission areas R-EA, G-EA and B-EA can be defined as a non-emission area. For example, an end portion of the color filter 500R, 500G and 500B on each pixel area PA can overlap the non-emission area. Thus, in the display apparatus according to the embodiment of the present disclosure, amount of the light emitted outside through the color filter 500R, 500G and 500B of each pixel area PA can be increased. Therefore, in the display apparatus according to the embodiment of the present disclosure, the light extraction efficiency can be improved.

A first barrier pattern 510 can be disposed on the non-emission area of the encapsulation structure 400. For example, the first barrier pattern 510 can overlap the bank insulating layer 160. The first barrier pattern 510 can be disposed side by side the color filters 500R, 500G and 500B. For example, the color filters 500R, 500G and 500B and the first barrier pattern 510 can be in direct contact with the third encapsulating layer 430. The end portion of each color filter 500R, 500G and 500B can overlap the first barrier pattern 510. For example, the first barrier pattern 510 can include a region disposed between the third encapsulating layer 430 and the end portion of each color filter 500R, 500G and 500B.

The first barrier pattern 510 can include a material blocking light. For example, the first barrier pattern 510 can include a black dye, such as carbon black. Thus, in the display apparatus according to the embodiment of the present disclosure, the light emitted from the light-emitting device 300 of each pixel area PA toward the color filter 500R, 500G and 500B of adjacent pixel area PA can be blocked by the first barrier pattern 510. Therefore, in the display apparatus according to the embodiment of the present disclosure, the light leakage due to emit the light which is not passing through the color filter 500R, 500G and 500B of each pixel area PA can be prevented. And, in the display apparatus according to the embodiment of the present disclosure, the unintentional mixing of the light can be prevented.

A filter passivation layer 550 can be disposed on the color filters 500R, 500G and 500B and the first barrier pattern 510. The filter passivation layer 550 can prevent the damage of the color filters 500R, 500G and 500B and the first barrier pattern 510 due to the external moisture and impact. The filter passivation layer 550 can include an insulating material. For example, the filter passivation layer 550 can include inorganic an insulating material and/or an organic insulating material. A thickness difference by the color filters 500R, 500G and 500B and the first barrier pattern 510 may be removed by the filter passivation layer 550. For example, an upper surface of the filter passivation layer 550 opposite to the encapsulation structure 400 can be flat. The upper surface of the filter passivation layer 550 can be parallel to the upper surface of the encapsulation structure 400.

An optical insulating layer 600 can be disposed on the filter passivation layer 550. The optical insulating layer 600 can include an insulating material. The optical insulating layer 600 can include a transparent material. For example, the optical insulating layer 600 can include an inorganic insulating material and/or an organic insulating material. The optical distance of the light emitted from the light-emitting device 300 of each pixel area PA can be sufficiently secured by the optical insulating layer 600. For example, the optical insulating layer 600 can have a greater thickness than at least one insulating layer 110, 120, 130, 140, 150 and 160 disposed between the device substrate 100 and the encapsulation structure 400. An upper surface of the optical insulating layer 600 opposite to the filter passivation layer 550 can be flat. For example, the upper surface of the optical insulating layer 600 can be parallel to the upper surface of the filter passivation layer 550.

A second barrier pattern 520 can be disposed in the optical insulating layer 600. For example, the optical insulating layer 600 can include a first optical insulating layer 610 and a second optical insulating layer 620 disposed on the first optical insulating layer 610, and the second barrier pattern 520 can be disposed between the first optical insulating layer 610 and the second optical insulating layer 620. A thickness difference due to the second barrier pattern 520 can be removed by the second optical insulating layer 620. The second optical insulating layer 620 can have a refractive index same as the first optical insulating layer 610. The second optical insulating layer 620 can include a same material as the first optical insulating layer 610. For example, a boundary between the first optical insulating layer 610 and the second optical insulating layer 620 can be not recognized at the outside of the second barrier pattern 520. Thus, in the display apparatus according to the embodiment of the present disclosure, the reflection of the light due to the difference in the refractive index can be prevented at the boundary between the first optical insulating layer 610 and the second optical insulating layer 620. Therefore, in the display apparatus according to the embodiment of the present disclosure, the decrease in the light extraction efficiency due to the boundary between the first optical insulating layer 610 and the second optical insulating layer 620 can be prevented.

The second barrier pattern 520 can include a material blocking light. For example, the second barrier pattern 520 can include a black dye, such as carbon black. The second barrier pattern 520 can include a same material as the first barrier pattern 510. The second barrier pattern 520 can overlap the first barrier pattern 510. For example, the second barrier pattern 520 can be disposed within the non-emission area. The second barrier pattern 520 can overlap the bank insulating layer 160. The second barrier pattern 520 can have a same size as the first barrier pattern 510 in the non-emission area. Thus, in the display apparatus according to the embodiment of the present disclosure, the traveling direction of the light emitted from the light-emitting device 300 of each pixel area PA may be limited by the first barrier pattern 510 and the second barrier pattern 520. Therefore, in the display apparatus according to the embodiment of the present disclosure, the decrease in the quality of the image due to the unintentional mixing of the light can be prevented.

Optical lenses OL can be disposed on the optical insulating layer 600. The optical lenses OL can be disposed side by side along the upper surface of the optical insulating layer 600. The optical lenses OL can extend parallel to each other in a direction. For example, in the display apparatus according to the embodiment of the present disclosure, the pixel areas PA can be disposed side by side in a first direction X and a second direction Y perpendicular to the first direction X, and each of the optical lenses OL can extend in an inclined direction with respect to the first direction X and the second direction Y. A horizontal width of each optical lens OL can be greater than a horizontal width of the emission area R-EA, G-EA and B-EA defined in each pixel area PA. For example, each of the optical lenses OL can include a region overlapping with the emission areas R-EA, G-EA and B-EA and a region overlapping with the bank insulating layer 160. The light in which the traveling direction is limited by the first barrier pattern 510 and the second barrier pattern 520 can be provided to the user through one of the optical lenses OL. The image by the light emitted from the light-emitting device 300 of each pixel area PA can be three-dimensionally recognized by the user by the optical lenses OL. The optical lenses OL can be lenticular lenses. For example, the display apparatus according to the embodiment of the present disclosure can be a light-field display apparatus (LFD) providing a three-dimensional image to the user in the light field method using the optical lenses OL.

Pixel lenses 700 can be disposed between the filter passivation layer 550 and the optical insulating layer 600. For example, the pixel lenses 700 can be disposed on the first barrier pattern 510, the second barrier pattern 520 can be disposed on the pixel lenses 700. The pixel lenses 700 can be spaced apart from the first barrier pattern 510 and the second barrier pattern 520. A size of each pixel lens 700 can be smaller than a size of each optical lens OL. For example, each of the optical lenses OL can overlap a plurality of pixel area PA disposed in the first direction X, the pixel lens 700 disposed on each pixel area PA does not overlap the pixel area PA adjacent the corresponding pixel area PA in the first direction X. A curvature of each pixel lens 700 can be different from a curvature of each optical lens OL. The pixel lenses 700 can include a different material from the optical lenses OL. A process of forming the pixel lenses 700 can be different from a process of forming the optical lenses OL. For example, the pixel lenses 700 can be formed by a reflow process.

The emission area R-EA, G-EA and B-EA of each pixel area PA can overlap one of the pixel lenses 700. For example, the color filter 500R, 500G and 500B of each pixel PA can overlap one of the pixel lenses 700. Thus, in the display apparatus according to the embodiment of the present disclosure, the travelling direction of the light passing through the color filter 500R, 500G and 500B of each pixel area PA can be controlled by the pixel lens 700 disposed on the corresponding pixel area PA.

The pixel lens 700 disposed on each pixel area PA can have a greater size than the emission area R-EA, G-EA and B-EA of the corresponding pixel area PA. For example, an end portion of each pixel lens 700 can be disposed on the non-emission area. The end portion of each pixel lens 700 can overlap the bank insulating layer 160. For example, the end portion of each pixel lens 700 can overlap the first barrier pattern 510 and the second barrier pattern 520. Thus, in the display apparatus according to the embodiment of the present disclosure, the amount of the light travelling toward the optical lenses OL can be increased. Therefore, in the display apparatus according to the embodiment of the present disclosure, the light extraction efficiency can be improved.

The pixel lenses 700 can be covered by the first optical insulating layer 610. For example, a thickness difference due to the pixel lenses 700 can be removed by the first optical insulating layer 610. A surface of each pixel lens 700 toward the optical lenses OL can be in direct contact with the first optical insulating layer 610. A refractive index of the first optical insulating layer 610 can be smaller than a refractive index of each pixel lens 700. Thus, in the display apparatus according to the embodiment of the present disclosure, the reflection of the light due to the difference in the refractive index can be prevented at the boundary between each pixel lens 700 and the first optical insulating layer 610. Therefore, in the display apparatus according to the embodiment of the present disclosure, the decrease of the light extraction efficiency due to the boundary between each pixel lens 700 and the first optical insulating layer 610 can be prevented.

The pixel lens 700 disposed on each pixel area PA can be spaced apart from the pixel lens 700 disposed on the pixel area PA adjacent to the corresponding pixel area PA in the first direction X. For example, each of the pixel lenses 700 can be spaced apart from adjacent pixel lens 700 in the first direction X. A region between adjacent pixel lenses 700 in the first direction X can overlap the first barrier pattern 510 and the second barrier pattern 520. Thus, in the display apparatus according to the embodiment of the present disclosure, the light passing through the color filter 500R, 500G and 500B of each pixel area PA can be emitted outside through the pixel lens 700 disposed on the corresponding pixel area PA. Therefore, in the display apparatus according to the embodiment of the present disclosure, the decrease in the quality of the image due to the unintentional mixing of the light can be prevented.

A diffusing layer 800 can be disposed between the optical insulating layer 600 and the optical lenses OL. The light emitted from the light-emitting device 300 of each pixel area PA can provide a portion of the diffusing layer 800 overlapping with the corresponding pixel area PA by the pixel lenses 700 and the second barrier pattern 520. The light provided to the diffusing layer 800 can be scatted. Thus, in the display apparatus according to the embodiment of the present disclosure, a portion of the diffusion layer 800 in which the light of each pixel area PA is provided by the pixel lenses 700 can be recognized as the emission point of the corresponding pixel area PA by the user. A portion of the diffusion layer 800 in which the light of each pixel area PA is provided by the pixel lenses 700 can be continuous with a portion of the diffusing layer 800 in which the light of adjacent pixel area PA is provided by the pixel lenses 700. For example, in the display apparatus according to the embodiment of the present disclosure, the emission point of each pixel area PA can be recognized as being continuous with the emission point of adjacent pixel area PA by the user.

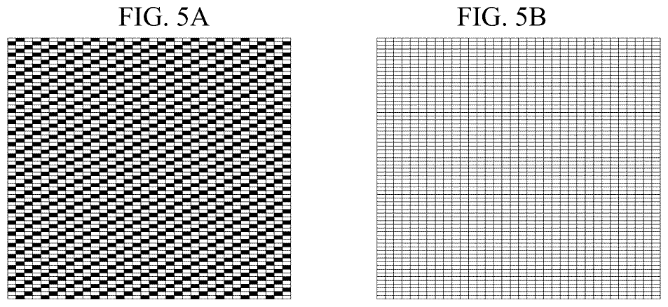

FIG. 5A is a view showing an image by a display apparatus without the pixel lenses 700 and the diffusing layer 800, and FIG. 5B is a view showing an image by the display apparatus according to the embodiment of the present invention.

Referring to FIG. 5A, in the image by the display apparatus without the pixel lenses 700 and the diffusing layer 800, the dark area by the second barrier pattern 520 can be enlarged by the optical lenses OL, such that the wave pattern due to the moire phenomenon can be recognized. However, referring to FIG. 5B, in the image by the display apparatus according to the embodiment of the present disclosure, the wave pattern due to the moire phenomenon cannot be recognized. That is, in the display apparatus according to the embodiment of the present disclosure, the second barrier pattern 520 enlarged by the optical lenses OL cannot be recognized by the user. Thus, in the display apparatus according to the embodiment of the present disclosure, the quality of the image recognized three-dimensionally by the user by the optical lenses OL can be improved.

Accordingly, the display apparatus according to the embodiment of the present disclosure can include the light-emitting devices 300, the color filters 500R, 500G and 500B, the pixel lenses 700, the optical insulating layer 600, the diffusing layer 800 and the optical lenses OL, which are disposed at or in the emission area R-EA, G-EA and B-EA of each pixel area PA, wherein the travelling direction of the light emitted from the light-emitting device 300 of each pixel area PA can be controlled by the one of the pixel lenses 700 and the second barrier pattern 520 disposed on the non-emission area, to provide a portion of the diffusing layer 800 overlapping with the corresponding pixel area PA. Thus, in the display apparatus according to the embodiment of the present disclosure, a portion of the diffusing layer 800 in which the light of each pixel area PA is provided can be recognized as the emission point of the corresponding pixel area PA by the user. That is, in the display apparatus according to the embodiment of the present disclosure, the second barrier pattern 520 enlarged by the optical lenses OL can be recognized by the user. Therefore, in the display apparatus according to the embodiment of the present disclosure, the decrease in the quality of the image three-dimensionally recognized by the user by the optical lenses OL can be prevented.

And, in the display apparatus according to the embodiment of the present disclosure, the light extraction efficiency can be improved by the pixel lenses 700 disposed between the color filter 500R, 500G and 500B of each pixel area PA and the optical insulating layer 600. Thus, in the display apparatus according to the embodiment of the present disclosure, low power driving can be possible. Therefore, in the display apparatus according to the embodiment of the present disclosure, power consumption can be reduced.

In the display apparatus according to the embodiment of the preset disclosure, the light emitted from the emission area R-EA, G-EA and B-EA of each pixel area PA can display a same color as the light emitted from the emission area R-EA, G-EA and B-EA of adjacent pixel area PA in the second direction Y. For example, in the display apparatus according to the embodiment of the present disclosure, the light emitted from the emission area R-EA, G-EA and B-EA of each pixel area PA can display a different color from the light emitted from the emission area R-EA, G-EA and B-EA of adjacent pixel area PA in the first direction X, and the light emitted from the emission area R-EA, G-EA and B-EA of each pixel area PA can display a same color as the light emitted from the emission area R-EA, G-EA and B-EA of adjacent pixel area PA in the second direction Y, as shown in FIG. 3. Thus, in the display apparatus according to the embodiment of the present disclosure, each of the pixel lenses 700 can extend in the second direction Y. Therefore, in the display apparatus according to the embodiment of the present disclosure, a process of forming the pixel lenses 700 on the pixel areas PA can be simplified.

A plane of the emission area R-EA, G-EA and B-EA defined in each pixel area PA can have a bar shape extending in the second direction Y. For example, a plane of the pixel lens 700 disposed on each pixel area PA can have a shape corresponding a plane of the emission area R-EA, G-EA and B-EA defined in the corresponding pixel area PA. A distance of the pixel lens 700 disposed on each pixel area PA in the first direction X can be greater than a distance of the emission area R-EA, G-EA and B-EA defined in the corresponding pixel area PA in the first direction X. Thus, in the display apparatus according to the embodiment of the present disclosure, the process efficiency can be improved without the decrease of the light extraction efficiency.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

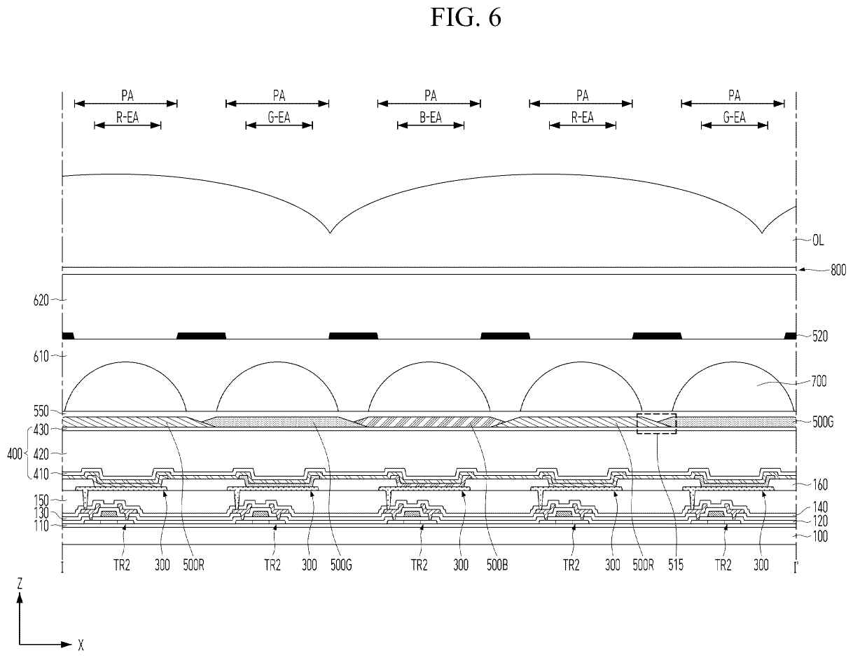

The display apparatus according to the embodiment of the present disclosure is described that the second barrier pattern 520 can include a same material as the first barrier pattern 510. However, in the display apparatus according to another embodiment of the present disclosure, the second barrier pattern 520 can include a different material from the first barrier pattern 510. For example, in the display apparatus according to the embodiment of the present disclosure, the first barrier pattern 515 can have a stacked structure of the color filters 500R, 500G and 500B which include different materials, as shown in FIG. 6. The color filter 500R, 500G and 500B of each pixel area PA can overlap the color filter 500R, 500G and 500B of adjacent pixel area PA on the non-emission area. Thus, in the display apparatus according to another embodiment of the present disclosure, a process of forming the first barrier pattern 510 can be simplified. Therefore, in the display apparatus according to another embodiment of the present disclosure, the production energy can be reduced by process optimization. And, in the display apparatus according to another embodiment of the present disclosure, the degree of freedom for the configuration and the material of the first barrier pattern 515 can be improved.

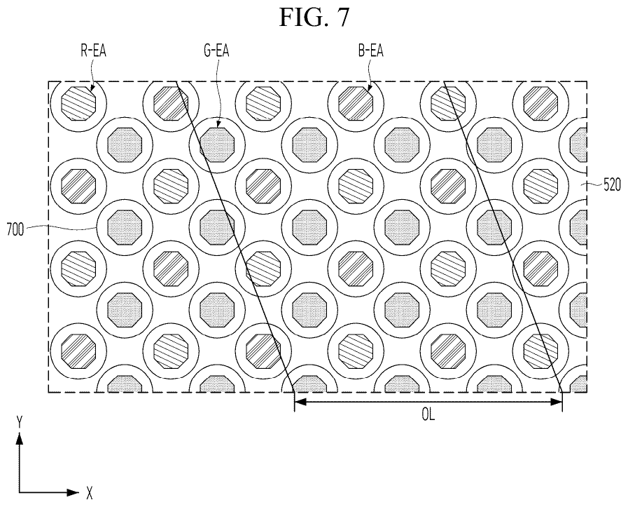

The display apparatus according to the embodiment of the present disclosure is described that the pixel lenses 700 can extend in the second direction Y. However, in the display apparatus according to another embodiment of the present disclosure, the pixel lens 700 disposed on each pixel area PA can be spaced apart from the pixel lens 700 disposed on adjacent pixel area PA in the first direction X, and the pixel lens 700 disposed on adjacent pixel area PA in the second direction Y. For example, in the display apparatus according to another embodiment of the present disclosure, the emission areas R-EA, G-EA and B-EA of the pixel areas can be arranged in a pentile shape, and each of the pixel lenses 700 can overlap one of the emission areas R-EA, G-EA and B-EA, as shown in FIG. 7. Thus, in the display apparatus according to another embodiment of the present disclosure, the degree of freedom for the arrangement and the plane shape of the pixel areas can be improved.

In the display apparatus according to another embodiment of the present disclosure, the plane of each pixel lens 700 can have a different shape from the plane of the emission area R-EA, G-EA and B-EA of each pixel area PA. For example, in the display apparatus according to the embodiment of the present disclosure, the plane of the emission area R-EA, G-EA and B-EA defined in each pixel area can have an octagonal shape, and the plane of each pixel lens 700 can have a circular shape, as shown in FIG. 7. Thus, in the display apparatus according to another embodiment of the present disclosure, the light emitted from the emission area R-EA, G-EA and B-EA of each pixel area can be effectively controlled by the pixel lens 700 of the corresponding pixel area. Therefore, in the display apparatus according to another embodiment of the present disclosure, the decrease in the quality of the image three-dimensionally recognized by the user by the optical lenses OL can be effectively prevented.

In the result, the display apparatus according to the embodiments of the present disclosure can comprise the first barrier pattern, the color filters, the pixel lenses, the second barrier pattern, the diffusing layer and the optical lenses, which are disposed on the light-emitting devices, wherein the color filters and the pixel lenses can overlap the emission areas in which the light-emitting devices are disposed, wherein the first barrier pattern and the second barrier pattern can be stacked outside the emission areas, and wherein the diffusing layer and the optical lenses can be stacked on the pixel lenses and the second barrier pattern. Thus, in the display apparatus according to the embodiments of the present disclosure, the visibility of the second barrier pattern can be decreased. That is, in the display apparatus according to the embodiments of the present disclosure, the second barrier pattern enlarged by the optical lenses cannot be recognized by the user. Thereby, in the display apparatus according to the embodiments of the present disclosure, the quality of the image three dimensionally recognized by the user by the optical lenses can be improved. And, in the display apparatus according to the embodiments of the present disclosure, the low power driving can be possible, and the power consumption can be reduced.

The above description has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A display apparatus, comprising:
a device substrate;
an emission area and a non-emission area;
a light-emitting device disposed at the emission area;
a color filter disposed on the light-emitting device, the color filter overlapping with the emission area;
a first barrier pattern disposed on the light-emitting device, the first barrier pattern overlapping with the non-emission area;
a pixel lens disposed on the color filter and the first barrier pattern, the pixel lens overlapping with the emission area;
a second barrier pattern disposed on the pixel lens, the second barrier pattern overlapping with the first barrier pattern;
an optical lens disposed on the pixel lens and the second barrier pattern, the optical lens overlapping with the emission area and the non-emission area; and
a diffusing layer disposed between the pixel lens and the optical lens and between the second barrier pattern and the optical lens.

2. The display apparatus according to claim 1, wherein the optical lens includes a different material from the pixel lens.

3. The display apparatus according to claim 1, wherein the pixel lens includes an end portion overlapping with the non-emission area.

4. The display apparatus according to claim 3, wherein the end portion of the pixel lens overlaps the first barrier pattern and the second barrier pattern.

5. The display apparatus according to claim 1, wherein the second barrier pattern is spaced apart from the pixel lens and the diffusing layer.

6. The display apparatus according to claim 5, wherein the second barrier pattern includes a same material as the first barrier pattern.

7. The display apparatus according to claim 5, further comprising:
a first optical insulating layer covering the pixel lens; and
a second optical insulating layer disposed on the first optical insulating layer,
wherein the second barrier pattern is disposed between the first optical insulating layer and the second optical insulating layer, and
wherein the diffusing layer and the optical lens are stacked on the second optical insulating layer.

8. The display apparatus according to claim 7, wherein the first optical insulating layer has a refractive index smaller than the pixel lens.

9. The display apparatus according to claim 1, wherein a curvature of the optical lens is different from a curvature of the pixel lens.

10. The display apparatus according to claim 1, wherein the light-emitting device includes a light-emitting layer disposed between a first electrode and a second electrode, and
wherein in operation, light generated by the light-emitting layer displays a same color as light passing through the color filter.

11. A display apparatus, comprising:
a bank insulating layer disposed on a device substrate, the bank insulating layer defining emission areas;
light-emitting devices disposed at the emission areas;
color filters disposed on the light-emitting devices, the color filters overlapping with the emission areas;
a first barrier pattern disposed side by side the color filters, the first barrier pattern overlapping with the bank insulating layer;
a second barrier pattern disposed on the first barrier pattern, the second barrier pattern overlapping with the bank insulating layer;
pixel lenses disposed between the first barrier pattern and the second barrier pattern, the pixel lenses overlapping with the emission areas;
a diffusing layer disposed on the second barrier pattern, the diffusing layer overlapping with the emission areas and the bank insulating layer; and
optical lenses disposed on the diffusing layer, the optical lenses extending parallel to each other in a direction,
wherein each of the optical lenses includes a region overlapping with a respective one of the emission areas and a region overlapping with the bank insulating layer.

12. The display apparatus according to claim 11, wherein each of the pixel lenses is spaced apart from an adjacent pixel lens on the bank insulating layer.

13. The display apparatus according to claim 11, wherein the second barrier pattern includes a different material from the first barrier pattern.

14. The display apparatus according to claim 13, wherein each of the color filters includes a different material from an adjacent color filter, and
wherein the first barrier pattern has a structure in which the color filters for displaying different colors are stacked.

15. The display apparatus according to claim 11, wherein each of the pixel lenses overlaps one of the emission areas, and
wherein a plane of each pixel lens has a different shape from a plane of the corresponding emission area.
